(19) United States
(12) Patent Application Publication
(10) Pub. No.: US 2012/0029851 A1
(43) Pub. Date: Feb. 2, 2012

(54) REMAINING CAPACITY DETECTING DEVICE AND BATTERY CONTROL IC

(75) Inventors: Yoko NAKAYAMA, Hitachinaka (JP); Takeshi Inoue, Hitachiota (JP)

(73) Assignee: RENESAS ELECTRONICS CORPORATION

(21) Appl. No.: 13/194,884

(22) Filed: Jul. 29, 2011

(30) Foreign Application Priority Data
Jul. 30, 2010 (JP) JP2010-171815

(51) Int. Cl. G06F 19/00; G01R 31/36

(52) U.S. Cl. 702/63

(57) ABSTRACT

A battery control IC includes a remaining amount estimation computing unit. The remaining amount estimation computing unit switches, during discharging of a battery pack, a first estimating method, in which a direct current resistance is obtained from a change in a voltage value of a battery voltage and a change in a current value of a current flowing through the battery pack at a start of discharging of the battery pack and a full charge capacity of the battery pack is obtained based on information set in advance indicating a relation between the direct current resistance and the full charge capacity, and a second estimating method, in which the full charge capacity of the battery pack is estimated from a relation between an open-circuit voltage predicted from the battery voltage and a used charge amount obtained from information of the current flowing through the battery pack.

### CROSS-REFERENCE TO RELATED APPLICATIONS

The present application claims priority from Japanese Patent Application No. 2010-171815 filed on Jul. 30, 2010, the content of which is hereby incorporated by reference to this application.

### TECHNICAL FIELD

The present invention relates to a battery control IC which controls charge and discharge of a secondary battery, and in particular to a method of accurately calculating a full charge capacity even after degradation of the secondary battery.

### BACKGROUND

In a secondary battery for consumer use such as the one in a notebook computer, it is important to let a user know the remaining capacity and the remaining time of the battery. In a battery control IC for a small-sized battery for consumer use, it is often the case that current integration is possible with high accuracy, and a method of obtaining the remaining capacity by subtracting a used charge amount from a full charge capacity is commonly used.

As described above, it is necessary to know the full charge capacity for the calculation of the remaining capacity using current integration. However, it is known that the full charge capacity is decreased with degradation of the battery. Thus, accurate estimation of the full charge capacity is indispensable for improving the calculation accuracy of the remaining capacity and the remaining time.

As a background art of this technical field, there is a technology described in U.S. Pat. No. 6,892,148 (Patent Document 1). This Patent Document 1 discloses a method of estimating a full charge capacity from an open-circuit voltage in a non-operating state before and after charging and discharging and a charged/discharged amount during the period.

Also, Japanese Unexamined Patent Application Publication No. 2007-024639 (Patent Document 2) discloses a method of estimating a full charge capacity by using a correlation between internal resistance and full charge capacity, although the method is for large-sized batteries. Specifically, the Patent Document 2 discloses a method in which “one pilot cell is discharged to detect the capacity of the pilot cell and a regression equation representing a correlation between internal impedance and capacity is created based on impedance measurement results and capacity detection results obtained so far, thereby estimating the capacity of remaining cells by using the created regression equation”.

### SUMMARY

The full charge capacity, which is indispensable for calculating the remaining capacity and the remaining time of a secondary battery by using current integration, is difficult to estimate accurately because the degradation state differs even in the same batteries depending on conditions of users such as frequency of use, environmental temperature and load.

In particular, in the method of calculating a full charge capacity from a previous value as disclosed in Patent Document 1, for a half of notebook computer users who do not frequently use the battery, a discrepancy occurs between the full charge capacity calculated at the time of previous charging or discharging and the full charge capacity of this time, and a calculation error in the remaining capacity and the remaining time is disadvantageously increased.

Also, in the method in which a pilot cell is discharged and the full charge capacity of other battery cells connected in series is obtained from a relation between internal resistance and full charge capacity like in the Patent Document 2, there is a problem that power of the pilot cell is wasted and the remaining time is shortened when this method is applied to a small-sized device with a small capacity. In a small-sized portable device, it is not practical to separately mount a capacitor or a storage battery for storing power for the pilot cell because such capacitor and storage battery lead to an increase in cost and weight.

Thus, an object of the present invention is to provide a battery control IC capable of improving an estimation accuracy of a remaining capacity and a remaining time by obtaining a full charge capacity in consideration of degradation of a battery even for a battery that is not frequently used.

The above and other objects and novel characteristics of the present invention will be apparent from the description of the present specification and the accompanying drawings.

The following is a brief description of an outline of the typical invention disclosed in the present application.

That is, in the typical invention, a computer switches, during discharging of a battery pack, a first estimating method, in which a direct current resistance is obtained from a change in a voltage value measured by a voltage measure and a change in a current value measured by a current measure at a start of discharging of the battery pack and a full charge capacity of the battery pack is obtained based on information set in advance indicating a relation between the direct current resistance and the full charge capacity, and a second estimating method, in which the full charge capacity of the battery pack is estimated from a relation between an open-circuit voltage predicted from the voltage obtained by the voltage measure and a used charge amount obtained from the current measure.

Also, a computer switches, during discharging of a battery pack, a first estimating method, in which a direct current resistance is obtained from a change in a voltage value of a battery voltage and a change in a current value of a current flowing through the battery pack at a start of discharging of the battery pack and a full charge capacity of the battery pack is obtained based on information set in advance indicating a relation between the direct current resistance and the full charge capacity, and a second estimating method, in which the full charge capacity of the battery pack is estimated from a relation between an open-circuit voltage predicted from the battery voltage and a used charge amount obtained from the information about the current flowing through the battery pack.

The effects obtained by typical embodiments of the invention disclosed in the present application will be briefly described below. That is, even for a battery that is not frequently used, a full charge capacity is obtained in consideration of degradation of the battery, thereby improving an estimation accuracy of a remaining capacity and a remaining time.

### BRIEF DESCRIPTION OF THE DRAWINGS

FIG. 1 is a configuration diagram showing the configuration of a battery pack including a battery control IC according to a first embodiment of the present invention;

FIG. 2 is a diagram showing an example of display by the battery control IC according to the first embodiment of the present invention;

FIG. 3 is a diagram showing another example of arrangement of battery cells in the battery pack including the battery control IC according to the first embodiment of the present invention;

FIG. 4 is a descriptive diagram for describing terms used in a process of calculating a full charge capacity by the battery control IC according to the first embodiment of the present invention;

FIG. 5 is a schematic diagram showing a general outline of the process of calculating a full charge capacity by the battery control IC according to the first embodiment of the present invention;

FIG. 6 is a diagram showing changes in current and voltage of a battery in the process of calculating a full charge capacity by the battery control IC according to the first embodiment of the present invention;

FIG. 7 is a diagram showing a relation between direct current resistance and full charge capacity used in the process of calculating a full charge capacity by the battery control IC according to the first embodiment of the present invention;

FIG. 8 is a diagram showing a relation between SOC and direct current resistance used in the process of calculating a full charge capacity by the battery control IC according to the first embodiment of the present invention;

FIG. 9 is a diagram showing a relation between SOC and OCV used in the process of calculating a full charge capacity by the battery control IC according to the first embodiment of the present invention;

FIG. 10 is a descriptive diagram for describing a method of obtaining a full charge capacity from SOC and integrated charge amount in the process of calculating a full charge capacity by the battery control IC according to the first embodiment of the present invention;

FIG. 11 is a diagram showing changes in full charge capacity used in the process of calculating a full charge capacity by the battery control IC according to the first embodiment of the present invention;

FIG. 12 is a flowchart showing a process of estimating a full charge capacity at the time of discharging by the battery control IC according to the first embodiment of the present invention;

FIG. 13 is a descriptive diagram for describing a method of calculating a full charge capacity by a battery control IC according to a second embodiment of the present invention;

FIG. 14 is a flowchart showing a process of estimating a full charge capacity at the time of discharging by the battery control IC according to the second embodiment of the present invention;

FIG. 15 is a diagram showing a relation between elapsed time and voltage used in a process of calculating a full charge capacity by the battery control IC according to the second embodiment of the present invention; and

FIG. 16 is a flowchart showing a process of estimating a full charge capacity at the time of discharging by a battery control IC according to a third embodiment of the present invention.

### DETAILED DESCRIPTION

Hereinafter, embodiments of the present invention will be described in detail with reference to the accompanying drawings. Note that components having the same function are denoted by the same reference symbols throughout the drawings for describing the embodiments, and the repetitive description thereof will be omitted.

### First Embodiment

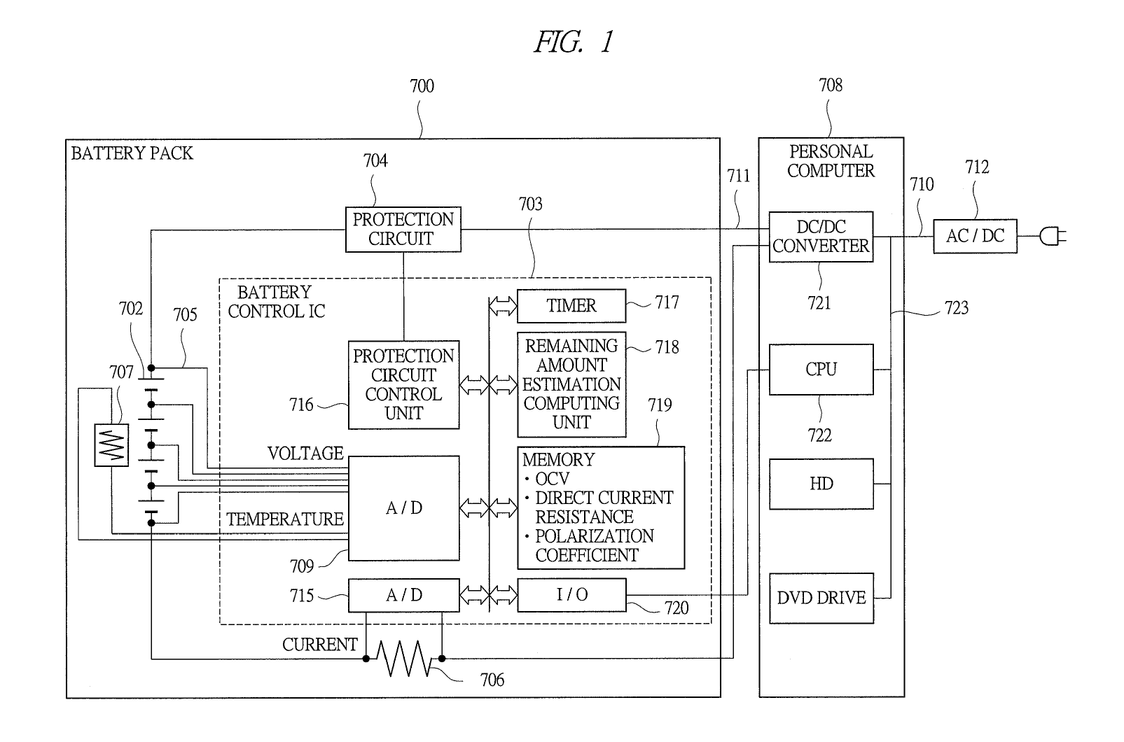

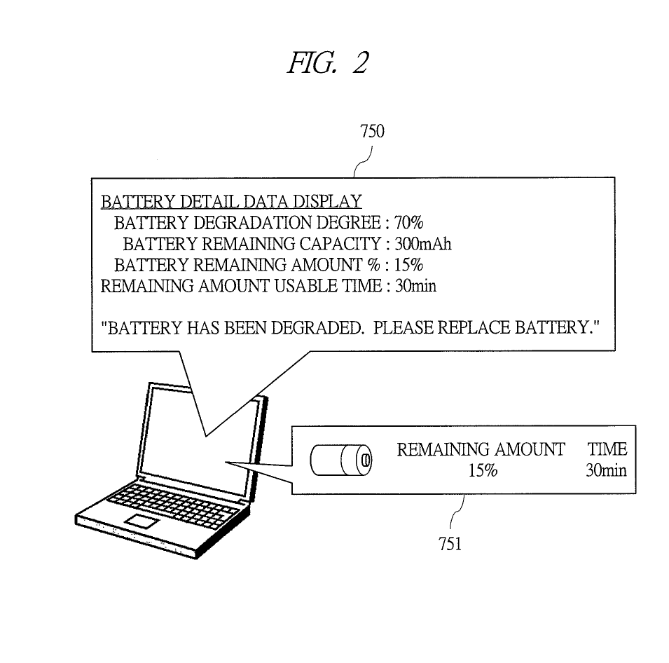

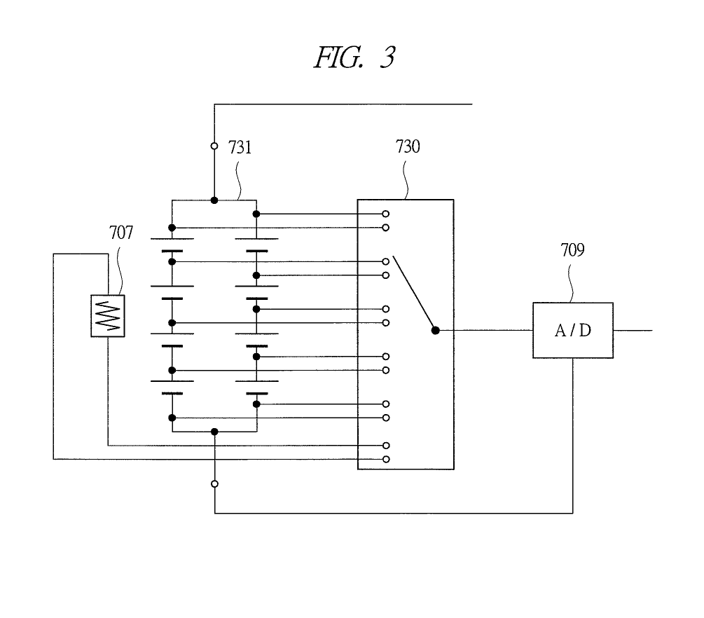

The configuration of a battery pack including a battery control IC and an example of display according to a first embodiment of the present invention will be described with reference to FIG. 1 to FIG. 3. FIG. 1 is a configuration diagram showing the configuration of the battery pack including the battery control IC according to the first embodiment of the present invention, and it shows an example of a battery pack for a notebook computer. FIG. 2 is a diagram showing an example of display by the battery control IC according to the first embodiment of the present invention, and FIG. 3 is a diagram showing another example of the arrangement of battery cells in the battery pack including the battery control IC according to the first embodiment of the present invention.

In FIG. 1, a battery pack 700 includes three-series or four-series battery cells 702, a battery control IC 703, a protection circuit 704, voltage detecting means 705, current detecting means 706 and temperature detecting means 707. The battery control IC 703, the voltage detecting means 705, the current detecting means 706 and the temperature detecting means 707 form a remaining capacity detecting device.

The battery control IC 703 includes an A/D converter 709, an A/D converter 715, a protection circuit control unit 716 connected to the protection circuit 704 for controlling the protection circuit 704, a timer 717, a remaining amount estimation computing unit 718, a memory 719 and an I/O 720 for communication with a notebook computer 708.

The voltage detecting means 705 and the current detecting means 706 are connected to the battery control IC 703. As for voltage, a voltage at both ends of each battery cell 702 is detected, and as for current, a current flowing through the battery cell 702 is detected. The detected voltage and the detected current are sent to a bus via the A/D converter 709 and the A/D converter 715, respectively.

As for temperature, the temperature detecting means 707, for example, a thermister or a thermocouple is disposed on the surface of the battery cells 702, and the detected temperature is sent to the bus via the A/D converter 709 like the voltage. The temperature detecting means 707 is preferably disposed at a location where battery temperature is predicted to be highest, for example, on a battery cell near a CPU 722 of the notebook computer 708 or on a battery cell near the center of the battery pack where heat tends to be trapped. The current is detected by the current detecting means 706, for example, a shunt resistor and is coupled to the bus via the other A/D converter 715.

The protection circuit control unit 716 performs control for ensuring safety of the battery, for example, the protection against overcharge and over discharge based on the values of current, voltage and temperature, and issues a command to the protection circuit 704. The remaining amount estimation computing unit 718 detects a state of the battery such as the remaining capacity and the remaining time by using information about current, voltage and temperature and information of an OCV table, a direct current resistance table and a polarization coefficient table stored in the memory 719.

The results thereof are communicated through the I/O 720 to the CPU 722 of the notebook computer 708, and the battery remaining capacity and remaining time are displayed on a monitor of the notebook computer 708.

For example, as depicted in a display screen 751 of FIG. 2, at the time of using the battery, the remaining amount and the remaining time are displayed in a small size at a lower end of a monitor. When a detail display screen 750 is separately started, detail information, for example, a battery degradation degree, a specific capacity and a guide for replacement is further displayed.

Although not shown, a display device or the like may be provided as display means on a battery pack 700 side so that the battery remaining capacity and other information can be displayed on the display device on the battery pack side.

Also, as depicted in FIG. 1, a power system for the notebook computer 708 includes a route 710 for supplying power from an AC power supply via an AC/DC converter 712 to the notebook computer 708 and a route 711 for supplying power from the battery cells 702 via a DC/DC converter 721 at the time of no plug connection.

From each route, power is supplied through a route 723 to each unit of the notebook computer 708 such as the CPU 722, a hard disk (HD) and a DVD drive. Also, at the time of charging the battery cells 702, the battery cells 702 are charged from the AC power supply via the AC/DC converter 712, the route 710, the DC/DC converter 721 and the route 711.

Note that, while the battery cells 702 are connected in series in the example depicted in FIG. 1, several sets of battery cells connected in series may be connected in parallel like in the configuration 731 depicted in FIG. 3. Although not shown in FIG. 1, the voltage of each battery cell and the temperature detection result of the temperature detecting means 707 are sequentially sent to the A/D converter with a switch denoted as 730 in FIG. 3. Also, the temperature detecting means 701 may be provided at a plurality of locations instead of one location.

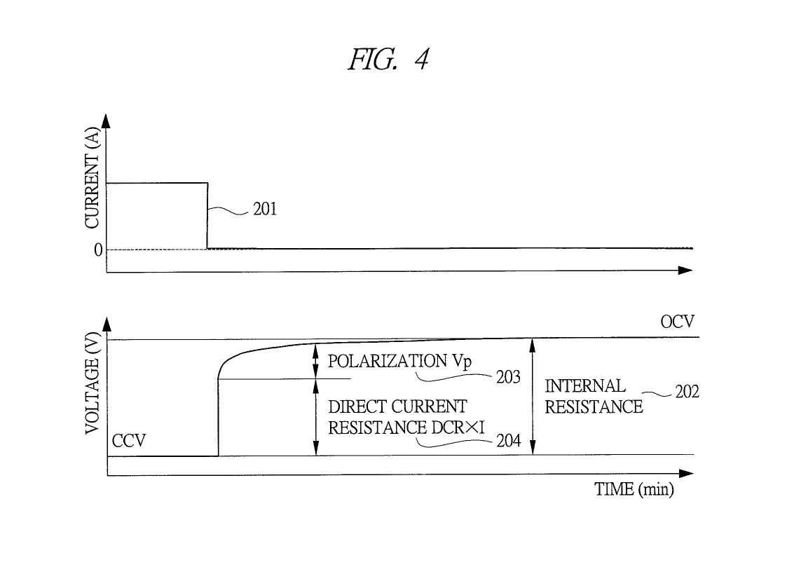

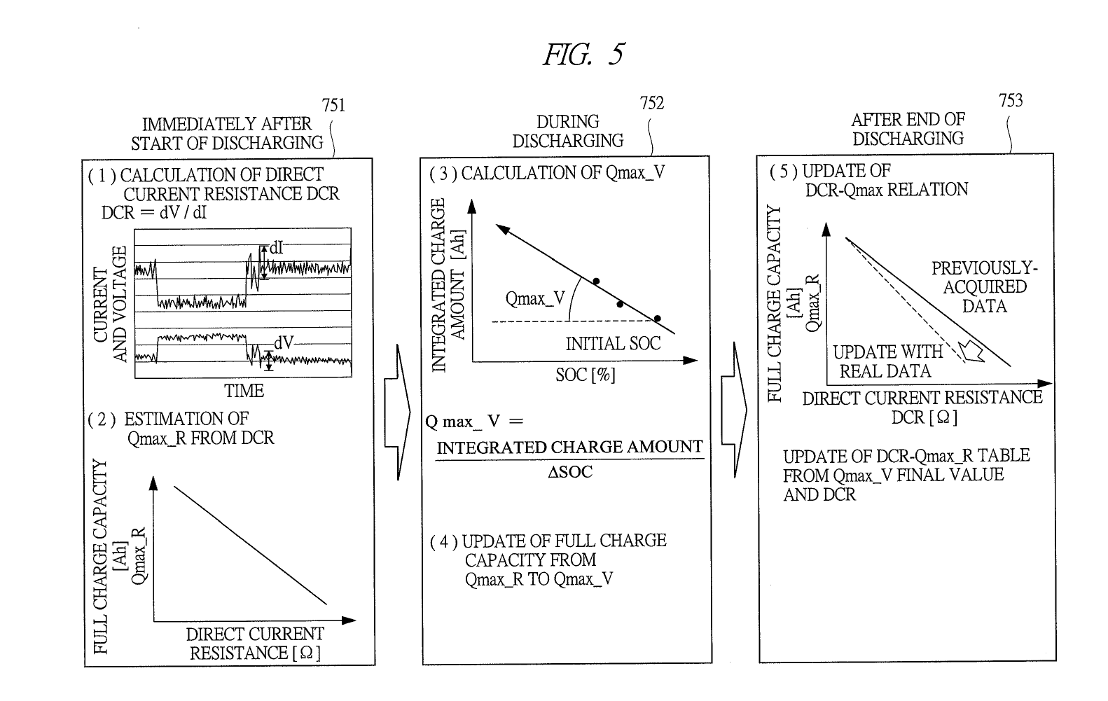

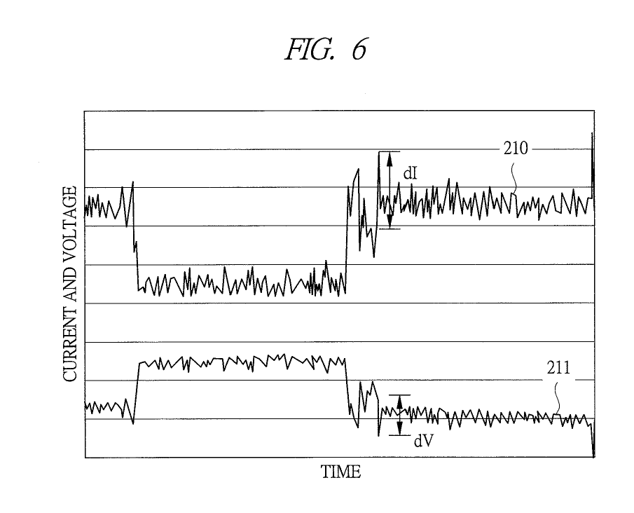

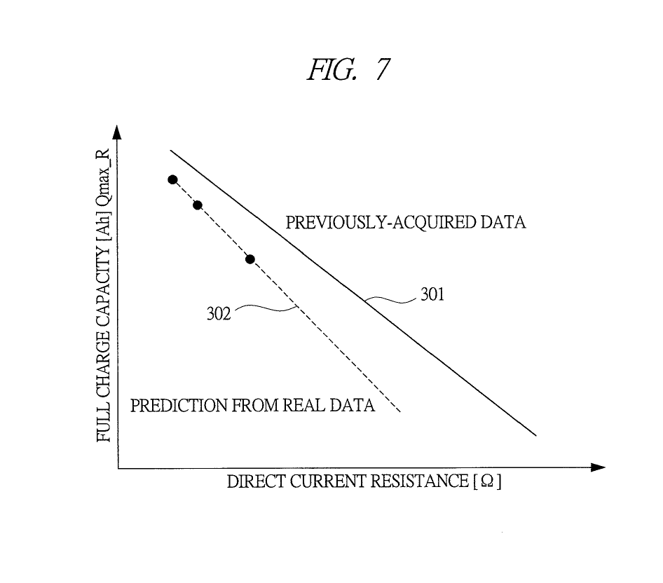

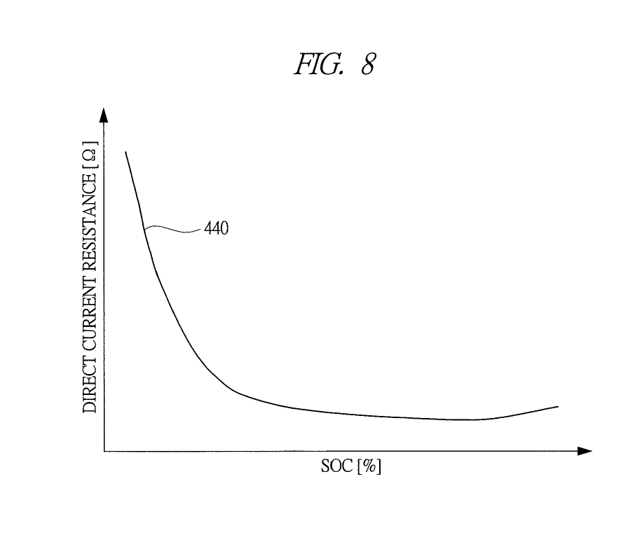

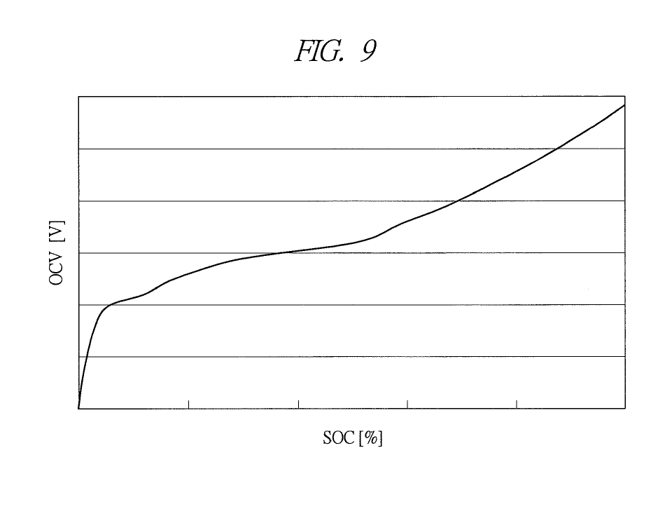

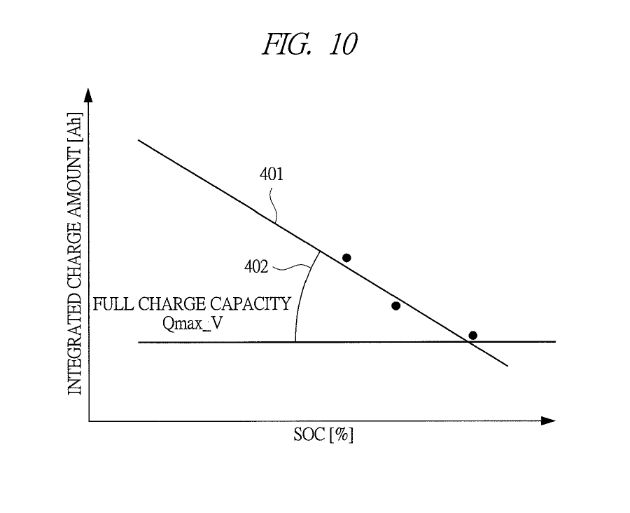

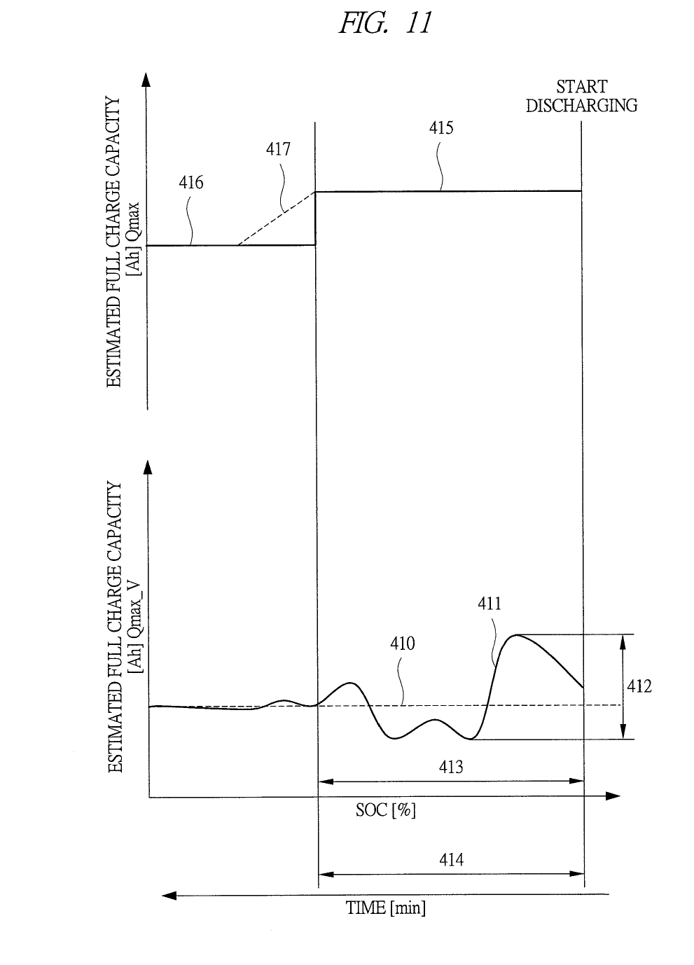

Next, a process of calculating a full charge capacity by the battery control IC according to the first embodiment of the present invention will be described with reference to FIG. 4 to FIG. 11. FIG. 4 is a descriptive diagram for describing the terms used in the process of calculating a full charge capacity by the battery control IC according to the first embodiment of the present invention. FIG. 5 is a schematic diagram showing a general outline of the process of calculating a full charge capacity by the battery control IC according to the first embodiment of the present invention. FIG. 6 is a diagram showing changes in current and voltage of a battery in the process of calculating a full charge capacity by the battery control IC according to the first embodiment of the present invention. FIG. 7 is a diagram showing a relation between direct current resistance and full charge capacity used in the process of calculating a full charge capacity by the battery control IC according to the first embodiment of the present invention. FIG. 8 is a diagram showing a relation between SOC and direct current resistance used in the process of calculating a full charge capacity by the battery control IC according to the first embodiment of the present invention. FIG. 9 is a diagram showing a relation between SOC and OCV used in the process of calculating a full charge capacity by the battery control IC according to the first embodiment of the present invention. FIG. 10 is a descriptive diagram for describing a method of obtaining a full charge capacity from SOC and integrated charge amount in the process of calculating a full charge capacity by the battery control IC according to the first embodiment of the present invention. FIG. 11 is a diagram showing changes in full charge capacity used in the process of calculating a full charge capacity by the battery control IC according to the first embodiment of the present invention.

In the present embodiment, the internal resistance of the battery cells 702 is represented as being divided into polarization and direct current resistance. A current waveform 201 shown in the upper part of FIG. 4 represents a situation in which a current is interrupted from a constant discharge state. A voltage shown in the lower part of FIG. 4 starts to change with the current interruption from a CCV (Close Circuit Voltage) first quickly and then gradually to reach an OCV (Open Circuit Voltage). At this time, in an internal resistance 202, a quick component 204 is handled as direct current resistance DCR×current I, and a slow component 203 is handled as polarization voltage Vp. The relation therebetween is represented in Equation 1 below.

OCV=CCV+(DCR×I)+Vp (Equation 1)

FIG. 5 depicts a general outline of a process of calculating a full charge capacity according to the present embodiment.

Immediately after starting the battery driving of the notebook computer 708 depicted in 751 of FIG. 5, (1) a direct current resistance is calculated from differences in current and voltage, and (2) a full charge capacity Qmax_R is obtained from a relation between direct current resistance and full charge capacity prepared in advance. Herein, although accuracy of the full charge capacity is not high, SOC (State of charge) and a remaining capacity are calculated based on the obtained value.

During discharging, as depicted in 752 of FIG. 5, (3) Qmax_V is obtained from a relation between SOC obtained from the voltage during discharging and a used charge amount. As the discharging time becomes longer, estimation accuracy of Qmax_V is improved. Then, when a predetermined condition is satisfied, (4) the full charge capacity is updated from Qmax_R to Qmax_V.

After the end of discharging, as depicted in 753 of FIG. 5, (5) a relation between direct current resistance and full charge capacity is updated based on the results in (1) and (3). By this means, a characteristic in accordance with a use environment of each battery can be obtained, and the estimation accuracy in (2) at the next startup can be improved.

Details will be described below.

A first full charge capacity calculating method of calculating a direct current resistance at the start of discharging depicted in 751 of FIG. 5 is described. As depicted in FIG. 6, during discharging, a current 210 and a voltage 211 change slightly. A difference in current dI and a difference in voltage dV at this time are obtained, and the direct current resistance is calculated by using Equation 2 below. Also, by restricting the difference in current dI to a predetermined value or higher, calculation accuracy of DCR can be improved.

DCR=dV/dI (Equation 2)

FIG. 7 depicts a relation between an internal resistance and a full charge capacity in a battery. It is known that there is a correlation between the internal resistance and the full charge capacity in a secondary battery such as a lead battery or a lithium-ion battery and the full charge capacity can be predicted from an internal resistance value. Furthermore, as shown by previously-acquired data 301 of FIG. 7, there is also a correlation between a direct current resistance which is a quick component of the internal resistance and the full charge capacity. A feature of the first full charge capacity calculating method lies in that, as described in the direct current resistance calculating method, when a change in current occurs during discharging, a direct current resistance can be obtained at relatively early timing after starting discharging, and the full charge capacity can be estimated from the relation depicted in FIG. 7. Here, since degradation is hardly observed in the calculated full charge capacity value when the system non-operating time is short, if a time from the previous end to the startup this time is equal to or shorter than a predetermined period, for example, one month, the previous value of the full charge capacity may be used as a full charge capacity immediately after the startup.

As the relation depicted in FIG. 7, a look-up table stored in advance in the memory or a correlation equation may be used. From the obtained direct current resistance, the full charge capacity Qmax_R is obtained by using a relation of the previously-acquired data 301 before commercialization depicted in FIG. 7 or the data 302 predicted from real data updated in (5) of FIG. 5.

Next, a second full charge capacity calculating method depicted in (3) of FIG. 5 is described. First, in calculating SOC during discharging, a general OCV calculating method is shown next.

An OCV can be measured after a lapse of a predetermined period of time (approximately two hours) from the operation stop. However, in the present embodiment, the OCV needs to be calculated during discharging. First, a voltage CCV during discharging is measured, and the OCV is calculated from Equation 1 described above.

The direct current resistance DCR in Equation 1 may be obtained by using Equation 2 described above in real time during discharging. Alternatively, by multiplying SOC-direct current resistance table data depicted in 440 of FIG. 8 measured in advance by a degradation factor and a temperature coefficient, a direct current resistance reflecting the battery state may be calculated.

For the estimation of polarization in Equation 1, for example, a method of approximation with a recurrence formula shown in Equation 3 below may be used. Coefficients in Equation 3 may be determined by applying an alternating current to a battery for use in advance and using an electrochemical impedance spectroscopy (EIS) (alternating current impedance method) (Masayuki Itagaki, “Electrochemical impedance method: principle, measurement and analysis”, Maruzen).

V(n)=a1V(n−1)+a2V(n−2)+ . . . +b1I(n)+b2I(n−1)+ (Equation 3)

From the polarization coefficient table stored in the memory, polarization coefficients a1, a2, . . . , b1, b2, . . . reflecting SOC, T and degradation are read. Then, a polarization voltage is predicted by using Equation 6. Here, V(n) is a voltage at the time n, and I(n) is a current at the time n.

By substituting the CCV, direct current resistance and polarization voltage mentioned above in Equation 1 above, an OCV is estimated during discharging, and then SOC is obtained from an OCV-SOC relation depicted in FIG. 9.

FIG. 10 depicts a relation 401 between SOC and an integrated charge amount q. As the integrated charge amount q, a value obtained by integration by the remaining amount estimation computing unit 718 shown in FIG. 1 or a value obtained by sequentially integrating currents by software is used.

As depicted in Equation 4 below, the full charge capacity Qmax_V can be calculated from ΔSOC and the integrated charge amount q, and a gradient 402 of a graph depicted in FIG. 10 corresponds to the full charge capacity Qmax_V.

ΔSOC=q/Qmax_{—}V (Equation 4)

When data about SOC and the integrated charge amount are stored during discharging to predict a full charge capacity, an estimation error is initially large as indicated by 411 of FIG. 11, but the full charge capacity Qmax_V comes closer to a true value 410 as SOC decreases by discharging and the use time becomes longer, and the estimation accuracy is improved. By this method, the full charge capacity Qmax_V can be made more accurate during discharging.

Next, a method of updating the full charge capacity from the result obtained in the first full charge capacity calculating method to the result obtained in the second full charge capacity calculating method in (4) of FIG. 5 is described.

The first full charge capacity calculating method can quickly estimate the full charge capacity, but it has a problem in accuracy. On the other hand, the second full charge capacity calculating method takes some time for estimation, but the accuracy thereof is high. In the present embodiment, by utilizing each of these characteristics described above, a provisional full charge capacity is first estimated by using the first full charge capacity calculating method at the start of discharging, and at the stage where an update condition is satisfied in the course of discharging, the full charge capacity is updated to the full charge capacity obtained by using the second full charge capacity calculating method.

The update condition of the full charge capacity is preferably a condition with which the estimation accuracy of the second full charge capacity calculating method is ensured. For example, as depicted in FIG. 11, when a change amount 412 of a Qmax_V estimated value within a predetermined period of time is equal to or smaller than a predefined value, it is determined that the estimated value is near a true value, and the full charge capacity is switched to the full charge capacity obtained by the second full charge capacity calculating method. Alternatively, the full charge capacity may be switched, for example, when an SOC difference 413 from the start of discharging depicted in FIG. 11 becomes equal to or larger than a predefined value or when a time 414 from the start of discharging becomes equal to or larger than a predefined value.

Also, in the full charge capacity updating method, the full charge capacity obtained by using the first full charge capacity calculating method indicated by 415 in FIG. 11 may be changed stepwise to the full charge capacity obtained by using the second full charge capacity calculating method indicated by 416 in FIG. 11. Alternatively, by gently changing the full charge capacity with interpolating the values before and after updating as indicated by 417 in FIG. 11, user's unpleasant feeling due to an abrupt change in the remaining amount display can be reduced.

Also, the full charge capacity obtained in the second full charge capacity calculating method indicated by 416 in FIG. 11 may be sequentially updated during discharging. Alternatively, by updating the full charge capacity only when the change amount of the full charge capacity is equal to or larger than a predetermined value, the calculation load can be reduced.

Next, updating of the relation between direct current resistance and full charge capacity shown in (5) of FIG. 5 is described.

In the first full charge capacity calculating method, if the use environment and use state of a device are approximately constant, the full charge capacity can be predicted from the previously-acquired data 301 of a degraded battery obtained before commercialization depicted in FIG. 7. However, in a device like the notebook computer 708 whose battery use frequency and use temperature environment are different depending on the user, history of battery degradation differs. Therefore, prediction from the previously-acquired data may possibly cause a deviation as the battery degradation proceeds.

Moreover, a general-purpose IC employing the full charge capacity calculating method of the present embodiment has to not only address a deviation among different products of the same type but also support various batteries from each manufacturer. An enormous number of processes are required to degrade these batteries before commercialization to obtain the previously-acquired data indicated by 301 of FIG. 7. For the solution of this problem, the relation depicted in FIG. 7 is updated every time after discharging with the accurate full charge capacity calculated in the second full charge capacity calculating method depicted in (3) of FIG. 5 and a direct current resistance value calculated during discharging. By this means, even the degradation of the batteries of different types and the different batteries of the same type can be accurately predicted in accordance with the features of respective usages.

In detail, after direct current resistances at several previous times and the full charge capacity Qmax_V at the end of discharging are stored, an approximate expression is obtained by, for example, a least squares method, and then a full charge capacity is obtained from a direct current resistance at the next discharging. However, since this relation is not necessarily able to be represented by a primary expression, the prediction is made by using a primary expression for convenience from data at several previous times or in a predetermined previous period instead of accumulating data from new products, thereby increasing the accuracy.

Also, as depicted in FIG. 8, the direct current resistance is largely changed due to SOC and temperature. Therefore, the direct current resistance used in updating is assumed to be set with a defined SOC and a defined temperature value. In the first full charge capacity calculating method, a direct current resistance under a predefined condition is estimated from SOC obtained during discharging, thereby estimating the full capacity. For this full capacity estimation, a look-up table or a correlation equation indicating the relation between SOC and direct current resistance depicted in FIG. 8 is used, and furthermore, temperature influences are required to be taken into consideration.

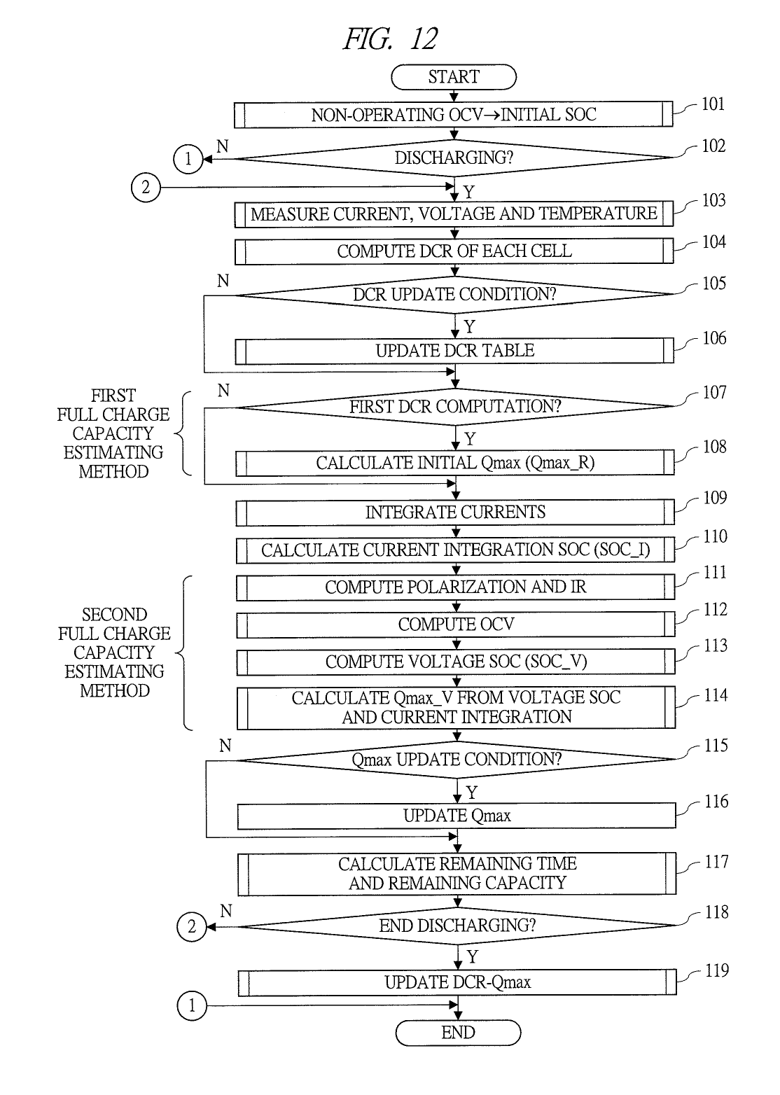

Next, a process of estimating a full charge capacity at the time of discharging by the battery control IC according to the first embodiment of the present invention will be described with reference to FIG. 12. FIG. 12 is a flowchart showing the process of estimating a full charge capacity at the time of discharging by the battery control IC according to the first embodiment of the present invention.

First, at step 101, an OCV (open-circuit voltage) is measured at predetermined intervals at the time of non-operation. Then, SOC at the start of discharging is calculated from the relation between OCV and SOC depicted in FIG. 11.

At step 102, whether to start discharging is determined. When discharging starts, information of a load current, a voltage of each cell and the temperature of the battery pack is measured and obtained at step 103. At step 104, when a change equal to or larger than a predetermined current is observed, a direct current resistance of each cell is obtained. Since the calculated direct current resistances vary widely, it is preferable to average a plurality of pieces of data.

Although calculation may be performed for all cells at step 105 and subsequent steps, calculation load can be reduced by focusing on a cell with a maximum direct current resistance value (hereinafter referred to as a most degraded cell).

At step 105, it is determined whether the values satisfy an update condition in a table regarding SOC, temperature and direct current resistance. As decision conditions, for example, a direct current resistance change amount, a temperature change amount and an SOC change amount from current table values can be taken as indexes. When the direct current resistance update condition is satisfied, the procedure goes to step 106. When this condition is not satisfied, the procedure goes to step 107.

At step 106, the relation table of SOC, temperature and direct current resistance is updated. This table is used afterward at step 111 for predicting OCV and step 117 for estimating the remaining capacity. Also, an increase in direct current resistance may be calculated by multiplying an initial value by a degradation factor instead of updating the table, and in this case, the degradation factor is updated.

Step 107 and step 108 correspond to a process in the first full charge capacity calculating method. In step 107, it is determined whether the direct current resistance computation is to be performed for the first time. As described above, when an average value of direct current resistance is taken, this determination is made after a first averaging process. When the computation is to be performed for the first time, the procedure goes to step 108, and when the computation is for the second and subsequent times, the procedure goes to step 109.

At step 108, based on the relational expression between direct current resistance and full charge capacity or the look-up table, an initial full charge capacity Qmax_R is determined.

At step 109, currents during discharging are integrated to obtain a discharged amount. At step 110, by using the initial SOC obtained at step 101 and the discharged amount at step 109, a current SOC_I and remaining capacity are obtained by Equation 5 below.

SOC_{—}I=((Qmax_{—}R×initial SOC)−discharged amount)/Qmax_{—}R (Equation 5)

Step 111 to step 114 correspond to a process in the second full charge capacity calculating method. At step 111, an IR drop due to direct current resistance and polarization predicted from SOC and temperature are computed for calculating OCV in Equation 1 described above.

At step 112, from the values of the direct current resistance and polarization obtained at step 111, an OCV is predicted by using Equation 1.

At step 113, from the relation table between OCV and SOC depicted in FIG. 11, SOC_V is obtained.

At step 114, from the relation between SOC_V obtained in step 113 and the current integrated value obtained at step 109, a full charge capacity Qmax_V is calculated by using the relation represented in Equation 4.

At step 115, it is determined whether a condition for updating the full charge capacity is satisfied. When the condition is satisfied, the full charge capacity is updated at step 116. When the condition is not satisfied, the procedure goes to step 117.

Also, since accuracy of calculation of direct current resistance is decreased at a low temperature, estimation accuracy in the first full charge capacity calculating method is decreased. Therefore, it is effective to advance the update timing with the decrease in temperature. At step 117, a remaining time and a remaining capacity are calculated, and then output to the notebook computer 708.

At step 118, it is determined whether discharging ends. If discharging has not ended yet, the procedure returns to step 103. If discharging has ended, the relation between direct current resistance and full charge capacity used in the first full charge capacity calculating method is updated at step 119.

This value updating is performed because accuracy of the full charge capacity calculated by the second full charge capacity calculating method is thought to be high if discharging has been performed for a predetermined period of time as described above. When not only the most degraded cell but also all cells are used for updating the relational expression, the number of pieces of data is increased and the reliability of the relational expression or the table is improved.

The processes described above is performed by the remaining amount estimation computing unit 718 depicted in FIG. 1 in accordance with the software stored in advance in the memory 719, and thus, the battery control IC 703 capable of estimating a full charge capacity can be configured. The remaining capacity and the remaining time obtained from the results are sent from the battery control IC 703 to the notebook computer 708, and the situation of the battery is displayed in the form as depicted in 750 and 751 in FIG. 2 to the user. Also, this may be displayed on the battery pack body with LEDs and liquid crystal.

Also, by performing a part or all of the computation in the processes described above not only in the battery control IC 703 but also in the notebook computer 708 in FIG. 1, calculation load on the battery control IC 703 can be reduced, and software update can be performed.

### Second Embodiment

In a second embodiment, a relation between elapsed time and full charge capacity is used for the first full charge capacity calculating method in the first embodiment.

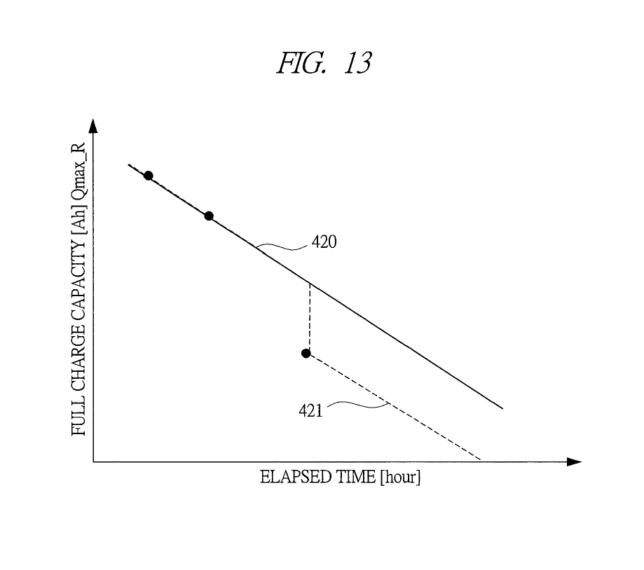

A full charge capacity calculating method by the battery control IC according to the second embodiment of the present invention will be described with reference to FIG. 13. FIG. 13 is a descriptive diagram for describing a method of calculating a full charge capacity by the battery control IC according to the second embodiment of the present invention. The configuration of the battery control IC 703 is similar to that of the first embodiment.

For a battery pack whose temperature and use method are under an approximately constant condition, as indicated by 420 in FIG. 13, a correlation of the full charge capacity not only with direct current resistance but also with elapsed time can be observed. When an elapsed time is used, the timer 717 for detecting an elapsed time is required, but since burdensome calculation of a direct current resistance can be omitted, the calculation load can be reduced. Also, since resistance calculation for obtaining a full charge capacity is not required, a full charge capacity can be instantaneously obtained after the start of discharging.

However, under a condition significantly different from normal, for example, when the battery pack is placed on the hood of a vehicle under the scorching sun, the battery cells 702 are abruptly degraded, and a correlation between elapsed time and full charge capacity is degraded as indicated by 421 of FIG. 13, and as a result, estimation accuracy of a full charge capacity is decreased. Thus, in this case, it is required to update full charge capacity to the full charge capacity obtained in the second full charge capacity calculating method at an earliest possible stage during discharging.

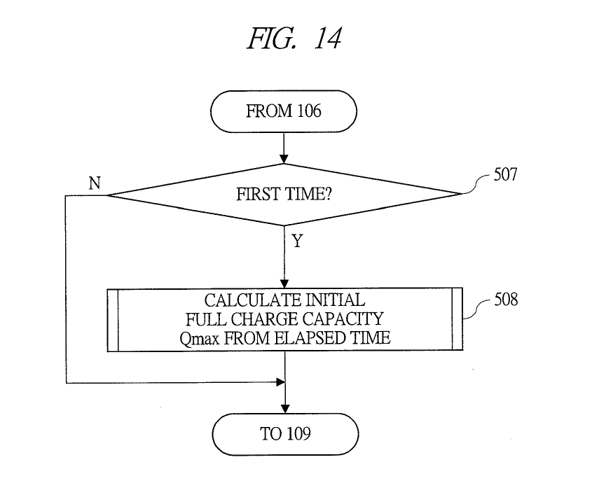

Next, a process of estimating a full charge capacity at the time of discharging by the battery control IC according to the second embodiment of the present invention will be described with reference to FIG. 14. FIG. 14 is a flowchart showing a process of estimating a full charge capacity at the time of discharging by the battery control IC according to the second embodiment of the present invention. FIG. 14 shows only processes different from those in the flowchart of the first embodiment depicted in FIG. 12, and other processes are similar to those in the first embodiment.

The flowchart depicted in FIG. 14 is to replace step 107 and step 108 of the flowchart depicted in FIG. 12.

In the present embodiment, it is determined at step 507 whether the process is to be performed for the first time after discharging, and at step 508, an initial full charge capacity is obtained from the elapsed time read from the timer by using the relation indicated by 420 in FIG. 13.

In the present embodiment, since the full charge capacity is obtained from the elapsed time, the full charge capacity can be instantaneously obtained. Also, under a condition significantly different from normal, the full charge capacity is obtained at an early stage by using the second full charge capacity calculating method, thereby preventing the deterioration of estimation accuracy.

### Third Embodiment

In a third embodiment, the second full charge capacity calculating method is used not during discharging but after the end of discharging to calculate a full charge capacity unlike the first embodiment, thereby updating the equation of the first full charge capacity calculating method.

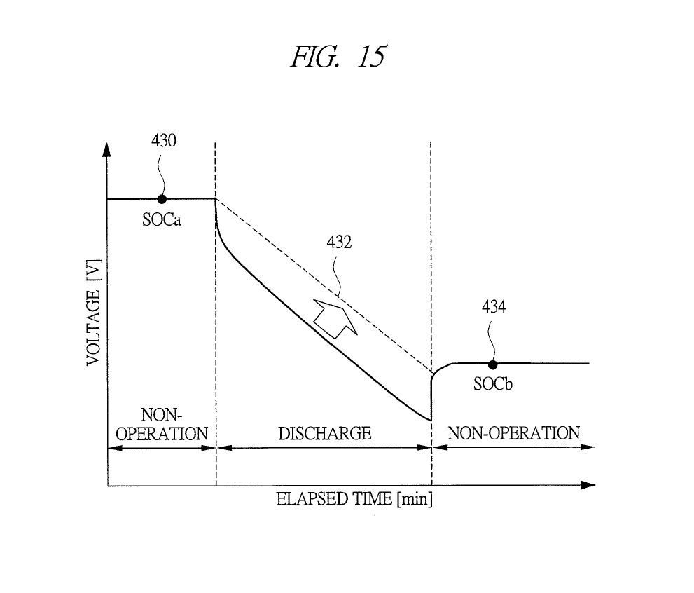

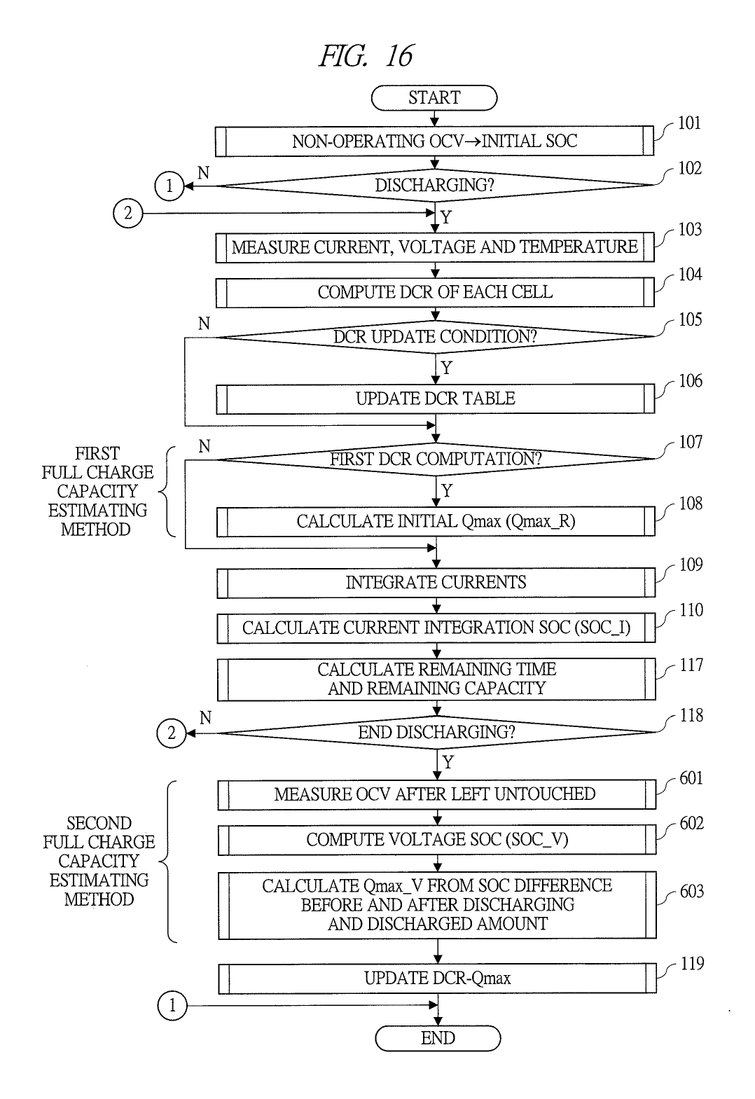

A process of estimating a full charge capacity at the time of discharging by the battery control IC according to the third embodiment of the present invention will be described with reference to FIG. 15 and FIG. 16. FIG. 15 is a diagram showing a relation between elapsed time and voltage used in a process of calculating a full charge capacity by the battery control IC according to the second embodiment of the present invention. FIG. 16 is a flowchart showing a process of estimating a full charge capacity at the time of discharging by a battery control IC according to a third embodiment of the present invention. The configuration of the battery control IC 703 is similar to that of the first embodiment.

FIG. 15 depicts a relation between elapsed time and voltage. In the first embodiment, as indicated by 432 in FIG. 15, OCV (dotted line) is predicted from CCV (solid line) during discharging, and a full charge capacity is calculated by using Equation 4 described above. In the present embodiment, from SOCa during non-operation before discharging indicated by 430 in FIG. 15 and SOCb during non-operation after discharging for a predetermined period of time indicated by 434 in FIG. 15 and from a discharged amount dq between a and b, a full charge capacity is calculated by using Equation 6 below.

Qmax_{—}V=dq/(SOCa−SOCb) (Equation 6)

In this method, since it is not required to predict OCV during discharging and actual measurement is performed, a full charge capacity can be predicted with simple calculation, and calculation load is reduced. Although the full charge capacity cannot be updated during discharging, by updating the relation between full charge capacity and direct current resistance (or time) used in the first full charge capacity calculating method with the second full charge capacity calculating method like in the first embodiment, a full charge capacity can be estimated at the start of discharging.

Next, a process of estimating a full charge capacity at the time of discharging by the battery control IC according to the third embodiment of the present invention will be described with reference to FIG. 16. FIG. 16 is a flowchart showing a process of estimating a full charge capacity at the time of discharging by a battery control IC according to the third embodiment of the present invention.

First, processes up to step 110 are similar to those in the first embodiment, and therefore are not described herein. In the present embodiment, since a full charge capacity is not updated during discharging, a remaining time and a remaining capacity are calculated at step 117 after step 110. Next, it is determined whether discharging has ended at step 118.

After the determination of the end of discharging, at step 601, after the battery is left untouched for a predetermined period of time from the end of discharging and when the voltage reaches OCV, the OCV is measured. Alternatively, OCV may be predicted from a voltage after a predetermined period of time from the end of discharging. At step 602, SOC is derived from OCV from the relation depicted in FIG. 11.

At step 603, as described above, a full charge capacity is calculated from an SOC difference before and after discharging and a discharged amount during discharging.

At step 119, from the full charge capacity calculated at step 603 and the direct current resistance calculated at step 104, the relation between direct current resistance and full charge capacity used in the first full charge capacity calculating method is updated.

In the foregoing, typical three embodiments have been described. The first full charge capacity calculating method may be replaced by another method capable of obtaining a full charge capacity immediately after the start of discharging. Also, the second full charge capacity calculating method may be replaced by another method capable of accurately obtaining a full charge capacity during discharging or after the end of discharging.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention relates to a battery control IC which controls charge and discharge of a secondary battery, and it can be widely applied to ICs which require accurate calculation of a full charge capacity.

What is claimed is:

1. A remaining capacity detecting device comprising:
a voltage measure which measures a battery voltage of each secondary battery cell in a battery pack including a plurality of secondary battery cells;
a current measure which measures a current flowing through the battery pack;
a temperature measure which measures a temperature of the battery pack; and
a computer which detects a remaining capacity of the battery pack based on measurement results of the voltage measure, the current measure, and the temperature measure,
wherein the computer switches, during discharging of the battery pack, a first estimating method, in which a direct current resistance is obtained from a change in a voltage value measured by the voltage measure and a change in a current value measured by the current measure at a start of discharging of the battery pack and a full charge capacity of the battery pack is obtained based on information set in advance indicating a relation between the direct current resistance and the full charge capacity, and a second estimating method, in which the full charge capacity of the battery pack is estimated from a relation between an open-circuit voltage predicted from the voltage obtained by the voltage measure and a used charge amount obtained from the current measure.

2. The remaining capacity detecting device according to claim 1,
wherein, in the first estimating method, before and after an end of discharging of the battery pack, the information indicating the relation between the direct current resistance and the full charge capacity is updated based on the full charge capacity obtained in the second estimating method and the direct current resistance measured during discharging.

3. The remaining capacity detecting device according to claim 2,
wherein, in the first estimating method, the full charge capacity of the battery pack is obtained based on information set in advance indicating a relation between an elapsed time and the full charge capacity.

4. The remaining capacity detecting device according to claim 3,
wherein the computer advances a timing of switching from the first estimating method to the second estimating method when the battery pack is placed in a temperature environment of 40° C. or higher during a storage period.

5. The remaining capacity detecting device according to claim 4,
wherein, in the second estimating method, the full charge capacity is estimated after an end of discharging of the battery pack from a relation between an open-circuit voltage actually measured by the voltage measure in a non-operation of the battery pack and a used charge amount obtained from the current measure during discharging of the battery pack.

6. The remaining capacity detecting device according to claim 5,
wherein the computer advances a timing of switching from the first estimating method to the second estimating method when the temperature measured by the temperature measure is lower than room temperature.

7. The remaining capacity detecting device according to claim 6,
wherein, when switching an estimated value of the full charge capacity by the first estimating method and an estimated value of the full charge capacity by the second estimating method, the computer gradually makes a change between the estimated value of the full charge capacity by the first estimating method and the estimated value of the full charge capacity by the second estimating method.

8. The remaining capacity detecting device according to claim 7,
wherein, in the first estimating method, when a time from a previous end to a startup this time falls below a predetermined time, a previous value is used.

9. The remaining capacity detecting device according to claim 8, further comprising:
a display which displays a battery remaining capacity calculated from the full charge capacity estimated by the computer and the used charge amount obtained from the current measure.

10. A battery control IC comprising:
an input circuit which inputs information about a battery voltage of each secondary battery cell in a battery pack including a plurality of secondary battery cells, information about a current flowing through the battery pack and information about a temperature of the battery pack; and
a computer which detects a remaining capacity of the battery pack based on the information about the battery voltage, the information about the current flowing through the battery pack and the information about the temperature of the battery pack input from the input circuit,
wherein the computer switches, during discharging of the battery pack, a first estimating method, in which a direct current resistance is obtained from a change in a voltage value of the battery voltage and a change in a current value of the current flowing through the battery pack at a start of discharging of the battery pack and a full charge capacity of the battery pack is obtained based on information set in advance indicating a relation between the direct current resistance and the full charge capacity, and a second estimating method, in which the full charge capacity of the battery pack is estimated from a relation between an open-circuit voltage predicted from the battery voltage and a used charge amount obtained from the information about the current flowing through the battery pack.

11. The battery control IC according to claim 10,
wherein the computer updates, before and after an end of discharging of the battery pack, the information indicating the relation between the direct current resistance and the full charge capacity based on the full charge capacity obtained in the second estimating method and the direct current resistance measured during discharging.

12. The battery control IC according to claim 11,
wherein, in the first estimating method, the full charge capacity of the battery pack is obtained based on information set in advance indicating a relation between an elapsed time and the full charge capacity.

13. The battery control IC according to claim 12,
wherein the computer advances a timing of switching from the first estimating method to the second estimating method when the battery pack is placed in a temperature environment of 40° C. or higher during a storage period.

14. The battery control IC according to claim 13,
wherein the computer estimates the full charge capacity after an end of discharging of the battery pack from a relation between an open-circuit voltage actually measured from the information of the battery voltage in a non-operation of the battery pack and a used charge amount obtained from the information of a current flowing through the battery pack during discharging of the battery pack.

15. The battery control IC according to claim 14,
wherein the computer advances a timing of switching from the first estimating method to the second estimating method when the information of temperature of the battery pack is lower than room temperature.

16. The battery control IC according to claim 15,
wherein, when switching an estimated value of the full charge capacity by the first estimating method and an estimated value of the full charge capacity by the second estimating method, the computer gradually makes a change between the estimated value of the full charge capacity by the first estimating method and the estimated value of the full charge capacity by the second estimating method.

17. The battery control IC according to claim 16,
wherein, in the first estimating method, when a time from a previous end to a startup this time falls below a predetermined time, a previous value is used.
